(19) United States
(12) Patent Application Publication
(10) Pub. No.: US 2008/0117661 A1
(43) Pub. Date: May 22, 2008

(54) Method, apparatus and system providing memory cells associated with a pixel array

(75) Inventors: Karl Holtzclaw, Boise, ID (US); Chen Xu, Boise, ID (US); Richard A. Mauritzson, Meridian, ID (US); Yangdon Chen, Pasadena, CA (US); Jeffrey Bruce, Meridian, ID (US); Xiangli Li, Boise, ID (US); Johannes Solhusvik, Haslum (NO)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/600,203

(22) Filed: Nov. 16, 2006

(51) Int. Cl. G11C 17/18; G11C 11/34

(52) U.S. Cl. 365/96; 365/104

(57) ABSTRACT

A method, apparatus, and system are disclosed providing an imaging device with memory cells containing anti-fuse elements located with or outside a pixel array. The memory cells are read out using control signal lines which are used to readout imaging pixels.

### FIELD OF THE INVENTION

This invention is related generally to memory cells, and more particularly to the use of such cells in an imaging device.

### BACKGROUND OF THE INVENTION

Imaging devices often have a need for a compact, one-time programmable, non-volatile memory. Potential uses include storage of a part ID, image related settings such as color balance, defective pixel information and/or customer information such as lens identity. Ideally at least some of this information should be customer programmable to allow sensor configuration after manufacturer delivery.

Non-volatile memory does not require power to maintain stored information and would thus provide a good choice in low-power, battery-operated products that are frequently left in an “off” position for long periods of time. Various types of non-volatile memories include read only memories (ROMs), erasable programmable read only memories (EPROMs), and electrically erasable programmable read only memories (EEPROMs).

A one-time programmable memory cell is a type of non-volatile memory cell that may not be reprogrammed after having once been programmed. A one time programmable memory cell may use an anti-fuse as the programmable element. The anti-fuse element exists in one of two states. In its initial state (“unprogrammed”) the anti-fuse element functions as an open circuit, preventing conduction of current through the anti-fuse element. Upon application of a high voltage or current, the anti-fuse is converted to a second state (“programmed”) in which the anti-fuse element functions as a line of connection permitting conduction of a current. During a readout of the cell, an unprogrammed anti-fuse element corresponds to one logic value, for example “0”, and a programmed anti-fuse element represents another logic value, for example “1”.

An anti-fuse element may be implemented using a capacitor or a MOSFET. When programming an anti-fuse MOSFET, the process begins with application of voltage stress to the MOSFET gate, which causes defects to appear in the gate-oxide. As the defect density increases, eventually a critical level is reached where a current may flow through the oxide through a chain of defects. The thermal effects of the current solidifies this newly formed conductive channel, or “pinhole,” through the oxide. When a capacitor is used as an anti-fuse element, programming causes a permanent short in the capacitor dielectric, allowing current to pass.

FIG. 1 illustrates a block diagram of one conventional CMOS imaging device 208 having a pixel array 200 which may have a need for associated memory. Pixel array 200 comprises a plurality of pixels arranged in a predetermined number of columns and rows. The pixels of each row in array 200 are all turned on at the same time by a row select line, and the pixels of each column are selectively output by respective column select lines. A plurality of row and column lines are provided for the entire array 200. The row lines are selectively activated in sequence by the row driver 210 in response to row address decoder 220, and the column select lines are selectively activated in sequence for each row activated by the column driver 260 in response to column address decoder 270. Thus, a row and column address is provided for each pixel. The CMOS imaging device 208 is operated by the control circuit 250, which controls address decoders 220, 270 for selecting the appropriate row and column lines for pixel readout, and row and column driver circuitry 210, 260, which apply driving voltage to the drive transistors of the selected row and column lines. The pixel output signals typically include a pixel reset signal, Vrst, taken off a pixel floating diffusion region when it is reset and a pixel image signal, Vsig, which is taken off the floating diffusion region after charges generated by an image are transferred to it. The Vrst and Vsig signals are read by a sample and hold circuit 265 and are subtracted by a differential amplifier 267 that produces a signal Vrst−Vsig for each pixel, which represents the amount of light impinging on the pixels. This difference signal is digitized by an analog to digital converter (ADC) 275. The digitized pixel signals are then fed to an image processor 280 which performs various pixel and/or image processing tasks and forms a digital image. The digitizing by ADC 275 and image processing by image processor 280 can be performed on or off the chip containing the pixel array 200.

In order to keep manufacturing costs low, a memory device which is provided in association with an imaging device, such as device 208 described above, preferably should not require extensive modifications of established manufacturing processes or consume a large amount of chip area. Existing memory devices with gate-oxide anti-fuse elements employ high peak currents during anti-fuse programming and the use of dedicated readout circuitry. High peak currents allow the fusing or melting of the oxide “pinhole” in a MOSFET or the dielectric breakdown in a capacitor, reducing its resistance, but require the use of large programming current and associated transistors that increase circuit size. The dedicated programming and readout circuitry further increases,circuit footprint and is difficult to integrate with an imaging device 208 such as described above. Existing implementations of gate-oxide anti-fuses also build the anti-fuse over an n-well to allow application of positive potential to the well during programming. This isolates the rest of the chip from the high voltages applied to the anti-fuse, but increases circuit size even further.

A method, apparatus and system providing one or more memory cells having an anti-fuse programmable element that may be easily integrated with existing imaging devices is therefore needed.

### BRIEF DESCRIPTION OF THE DRAWINGS

FIG. 1 is a block diagram of a conventional CMOS imaging device.

FIG. 2A is a schematic circuit diagram of an embodiment of a memory cell including an anti-fuse programmable element.

FIG. 2B is a schematic circuit diagram of another embodiment of a memory cell including an anti-fuse programmable element.

FIG. 2C is a schematic circuit diagram of a four-transistor pixel cell.

FIG. 3 is a block diagram of an embodiment of a CMOS imaging device employing a pixel array which includes the FIG. 2A, 2B, or 2C memory cell.

FIG. 3B is a block diagram of an embodiment of a CMOS imaging device having a separate memory cell array which includes the FIG. 2A, 2B, or 2C memory cell.

FIG. 3C is a block diagram of an embodiment of a CMOS imaging device having a separate memory cell array which includes the FIG. 2A, 2B, or 2C memory cell, separate control circuit, and separate read out circuitry.

FIG. 4 is a signal timing diagram for programming the memory cell of FIG. 2A, 2B, or 2C.

FIG. 5A is a signal timing diagram for reading the memory cell of FIG. 2A, 2B, or 2C.

FIG. 5B is an alternate signal timing diagram for reading the memory cell of FIG. 2A, 2B, or 2C.

FIG. 5C is a signal timing diagram for reading the memory cell of FIG. 2A, 2B, or 2C, with an anti-fuse element embodiment of FIG. 6B.

FIG. 6A is a semiconductor level view of an embodiment of an anti-fuse element over an n-well.

FIG. 6B is a semiconductor level view of an embodiment of an anti-fuse element over a p-well.

FIG. 7 is a block diagram of a processor system, e.g., a digital camera system, incorporating an embodiment of an imaging device containing the memory cell of FIG. 2.

### DETAILED DESCRIPTION OF THE INVENTION

In the following detailed description, reference is made to the accompanying drawings, which form a part hereof and illustrate specific embodiments in which the invention may be practiced. In the drawings, like reference numerals describe substantially similar components throughout the several views. These embodiments are described in sufficient detail to enable those skilled in the art to practice the invention, and it is to be understood that other embodiments may be utilized, and that structural, logical and electrical changes may be made within the bounds covered by the disclosure.

The terms “wafer” and “substrate” are to be understood as including silicon, silicon-on-insulator (SOI), or silicon-on-sapphire (SOS) technology, doped and undoped semiconductors, epitaxial layers of silicon supported by a base semiconductor foundation, and other semiconductor structures, as well as insulating substrates, such as quartz or glass. Furthermore, when reference is made to a “wafer” or “substrate” in the following description, previous process steps may have been utilized to form regions or junctions in the base semiconductor structure or foundation. In addition, the semiconductor need not be silicon-based, but could be based on silicon-germanium, germanium, or gallium-arsenide.

The term “pixel” refers to a picture element unit cell containing a photo-conversion device for converting electromagnetic radiation to an electrical signal. For purposes of illustration, a representative pixel is illustrated in the figures and description herein, and typically fabrication of all pixels in an image sensor will proceed simultaneously in a similar fashion.

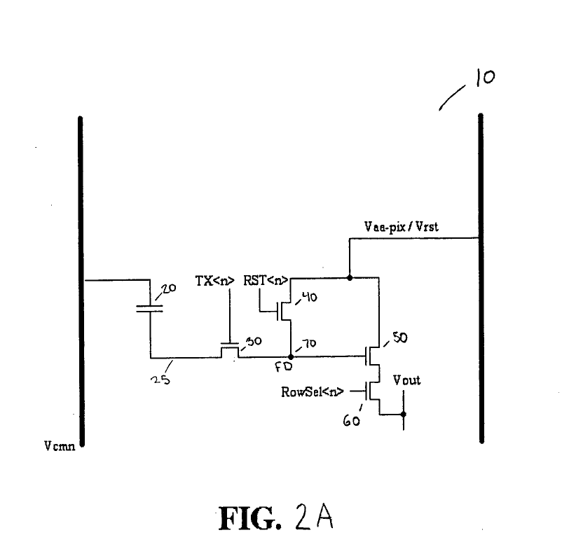

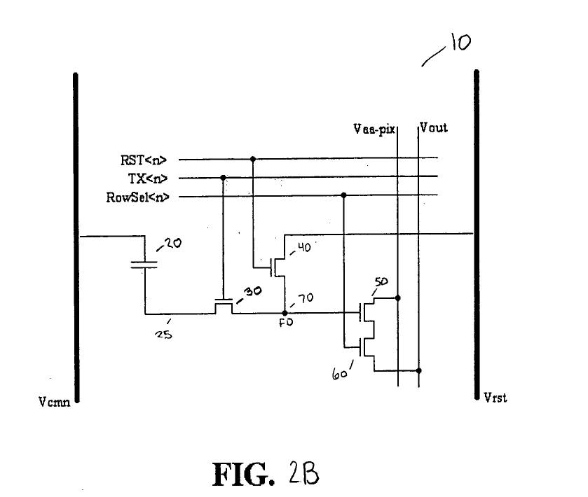

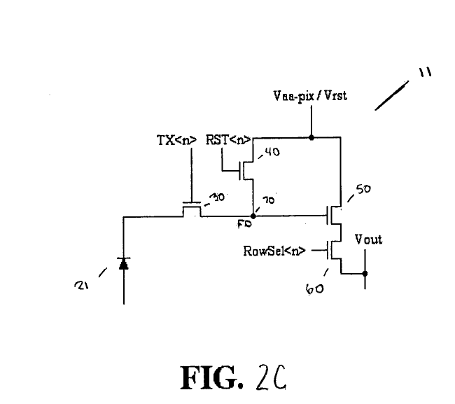

Referring now to the drawings, FIG. 2A illustrates an embodiment of an anti-fuse memory cell 10 (“memory cell”) based on a four-transistor CMOS pixel element. Memory cell 10 comprises an anti-fuse element 20, a transfer transistor 30, a reset transistor 40, a source-follower transistor 50, a row select transistor 60, and a storage region 70, for example, formed in a semiconductor substrate as a floating diffusion region. Anti-fuse element 20, which may be implemented using, for example, a capacitor or a MOSFET, is connected by a first node to a common voltage line Vcmn and connected by a second node to a source/drain terminal of transfer transistor 30. Transfer transistor 30 is controlled by signal TX applied to its gate, and is also connected by another source/drain terminal to storage region 70. Storage region 70 stores a charge corresponding to a programmed or unprogrammed state of the memory cell. Storage region 70 may be reset to a known voltage Vrst by reset transistor 40, which is controlled by a reset signal RST. Source-follower transistor 50, powered by a common supply voltage Vaa-pix and reset voltage Vrst, receives and amplifies a signal at its gate from storage region 70 for output on an output column line Vout. The output is controlled by row select transistor 60, which is controlled by row select signal RowSel and provides the output signal from source-follower transistor 50 to output column line Vout.

In another embodiment, shown in FIG. 2B, voltage lines Vaa-pix and Vrst are separate. This separation could be required for compatibility with existing pixel array 200 control signals.

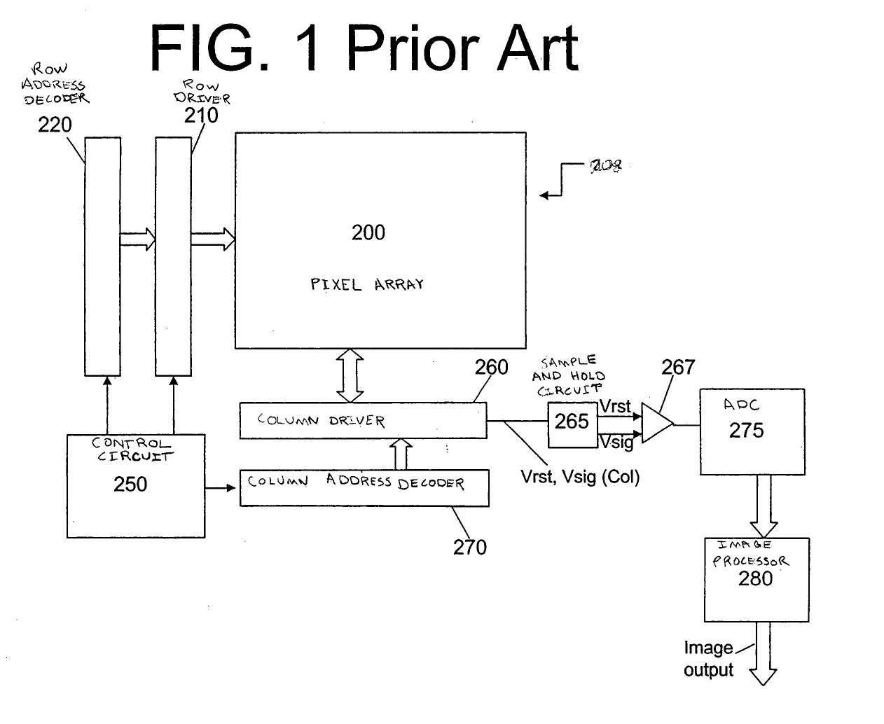

The signals RST, TX, and RowSel are the same signals used in a conventional four-transistor pixel of a pixel array 200. Likewise, the transistors 30, 40, 50, and 60, the floating diffusion region 70, and the voltage line Vaa-pix/Vrst, are elements typical in four-transistor pixel cells, as is well known in the art. For comparison purposes a conventional four transistor pixel 11, which can be used in array 200 of FIG. 1, is illustrated in FIG. 2C. As seen, the major differences of FIG. 2A or 2B over FIG. 2C is the replacement of a photosensor 21 with the anti-fuse element 20 and the connection of the anti-fuse element 20 to a voltage line Vcmn. Because of the similarities of the anti-fuse memory cell 10 to the conventional pixel cell 11 of FIG. 2C, memory cell 10 can easily be integrated in a pixel array 200 along with conventional four-transistor pixel 11 circuits. Memory cell 10 may be built using existing pixel cell manufacturing processes incurring a low additional cost for minor modifications, as will be described below. It should be noted that while pixel array 200 can employ four-transistor pixels 11 as shown in FIG. 2C, memory cell, 10 may also be incorporated in a pixel array 200 in which other pixel cell architectures, employing fewer or more than four transistors, are used.

During operation of the FIG. 2A pixel cell, a storage region 70 is reset by operation of a reset transistor 40. The reset charges in storage region 70 are read out through a source follower transistor 50 and row select transistor 60. After an image signal is integrated on photodiode 21 as image charges, they are transferred to storage region 70 where they are read out through transistors 50 and 60. Also, the pixel cell of FIG. 2A is shown as having a common supply voltage/reset voltage line Vaa-pix/Vrst, but separate lines may be provided for the respective reset 40 and source follower transistors in the manner illustrated in FIG. 2B.

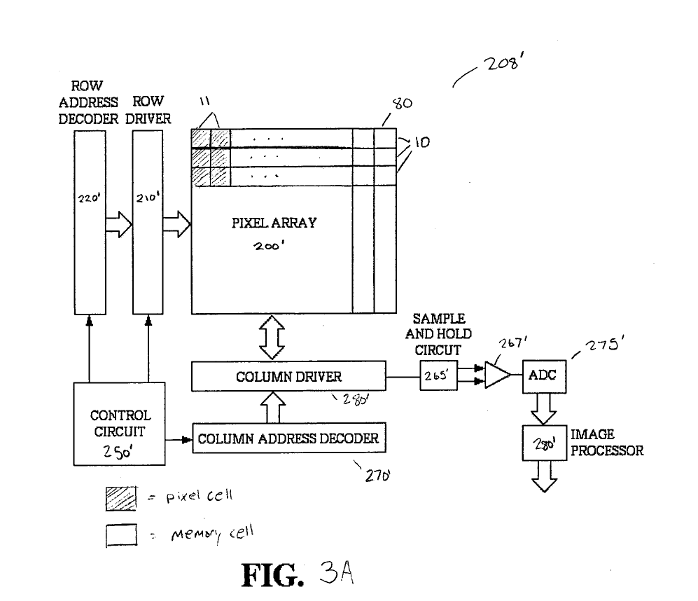

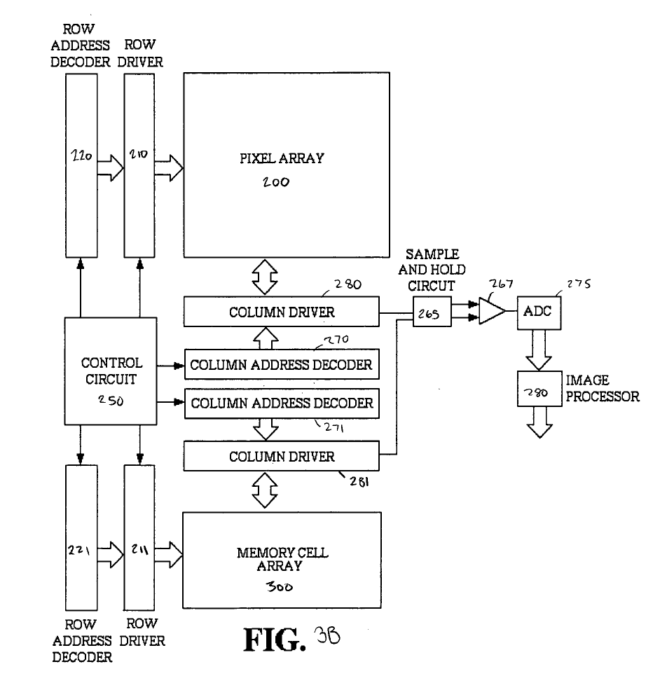

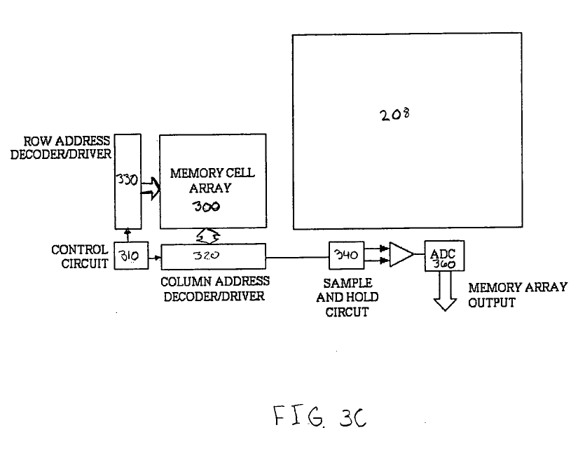

FIG. 3A further illustrates an imaging device 208′, which includes memory cells 10, for example, as illustrated in FIG. 2A or FIG. 2B in select columns of pixel array 200′. Memory cells 10 may occupy one or more full columns 80 or one or more portions of a column 80 and are aligned in rows with imaging pixel cells 11. Memory cell columns 80 can be located on an edge of pixel array 200′. Control circuit 250′ controls operation of pixel cells 11 within pixel array 200′ by supplying RST, TX and RowSel signals to a pixel cell, e.g., FIG. 2C, as well as the signals (RST, TX, and RowSel) and voltage levels (Vcmn, Vrst) to program and readout memory cells 10. Memory cells 10 and pixel cells 11 may therefore be electrically integrated within array 200′, sharing RST, TX, and RowSel lines with pixel cells 11 of the array 200′.

The memory cells 10 of FIG. 3A are shown as being integrated with pixel cells in array 200′, however, they may instead be contained within a separate memory cell array 300, as shown in the embodiment of FIG. 3B. In this embodiment, control circuit 250′ controls address decoders 221,271 and drivers 211,281 to control operations of memory array 300. Data in memory array 300 is read out through the same readout circuitry provided to read output from pixel array 200, including sample and hold circuit 265, differential amplifier 267, and analog-to-digital converter 275.

In another embodiment illustrated in FIG. 3C, memory cell array 300 is operated by a control circuit 310 entirely separate from the control circuit 250 which operates pixel array 200 of imaging device 208. Control circuit 310 controls separate column address decoders/drivers 320 and row address decoders/drivers 330 for memory cell array 300. Peripheral circuitry for reading out data from memory array 300 is also separate but similar to those which readout of pixel array 200 and may include a sample and hold circuit 340, differential amplifier 350 and analog to digital converter 360. It should be noted with a separate sample and hold circuit it may be advantageous to eliminate one of the sample hold caps and monitor only the final voltage level on the floating diffusion.

FIG. 4 shows a timing diagram for programming a selected memory cell 10. Vcmn is set to a programming voltage for the selected memory cell 10, e.g., in column 80 of FIG. 3A. The′ programming voltage, which depends in part upon the physical characteristics of the anti-fuse element 20, can be about 7V. The reset voltage line Vrst (FIG. 2) is set to ground. RST signal is pulsed high, turning on reset transistor 40 (FIG. 2). TX signal is pulsed high, turning on transfer transistor 30 (FIG. 2). With reset transistor 40 and transfer transistor 30 turned on, a circuit path exists from Vcmn, a positive voltage, to Vrst (ground) through the anti-fuse element 20, transfer transistor 20, and reset transistor 40. Accordingly, a programming voltage is applied to anti-fuse element 20 which is sufficient to produce a short circuit in anti-fuse element 20, thus programming memory cell 10.

The high programming voltage is larger than what is normally present in conventional pixel cells. Accordingly, to prevent thermal damage to cell 10 components or components of other parts of pixel array 200′ the doping levels in storage region 70 and in a diffusion region between transfer transistor 30 and anti-fuse element 20 can be increased to protect transfer transistor 30 and reset transistor 40 from hot carrier damage. Alternatively, other measures known in the art to reduce hot carrier damage at transfer transistor 30, reset transistor 40, and other transistors 50, 60 can be employed.

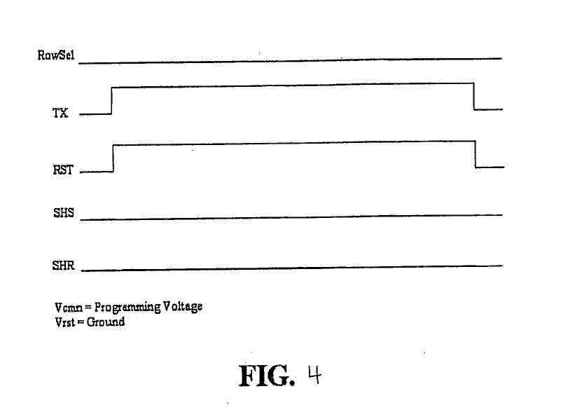

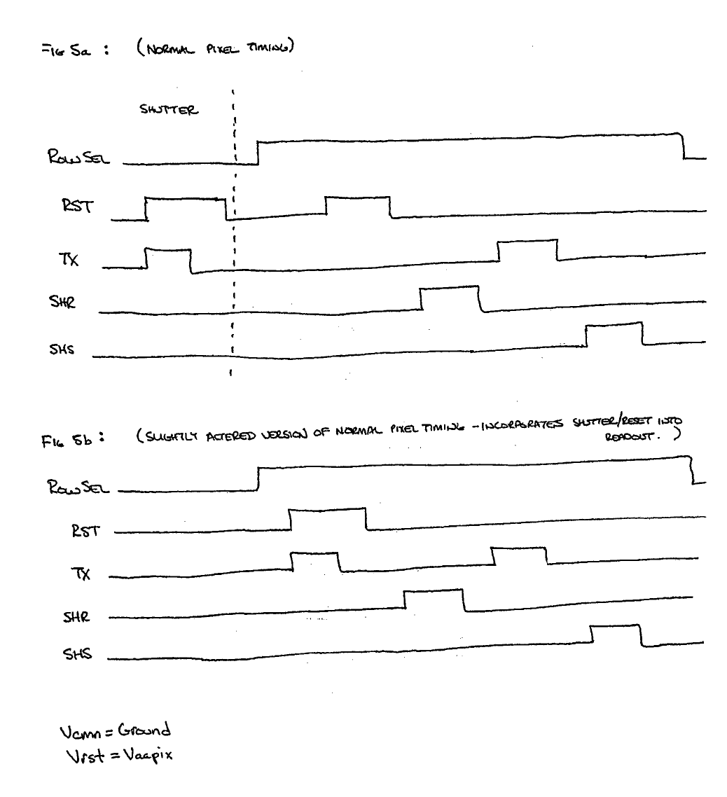

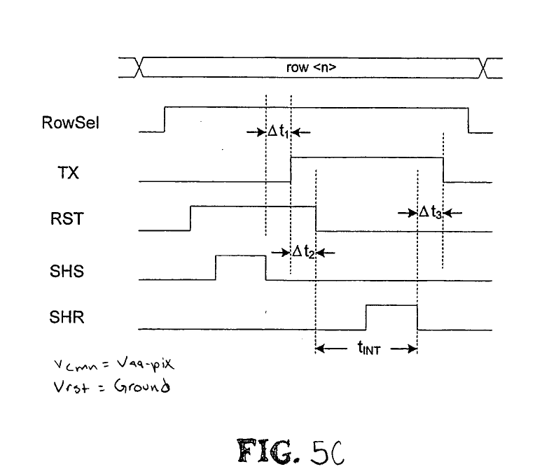

FIG. 5A shows a timing diagram for a readout of a memory cell 10 which corresponds to that of a normal pixel readout. In this readout, Vrst is set to Vaapix and Vcmn is set to ground during memory cell 10 readout. It may also be preferential to set Vcmn to a positive voltage during normal pixel operation to prevent a current draw. The readout timing shown provides a correlated double sampled output of the memory cells 10 which is similar to the correlated double sampled output provided for imaging pixels of array 200′. A correlated double sampling readout is easy to implement since the existing circuitry for carrying out the operation already exists for the imaging pixels of array 200′.

A correlated double sampling readout of a memory cell 10 is initiated by simultaneously pulsing RST signal and TX signal high to set region 25 and floating diffusion region 70 to a positive potential. A RowSel signal is pulsed high to select a pixel row for readout. Then RST signal is pulsed high while the reset supply voltage remains set to Vaapix, thereby resetting floating diffusion region 70 to a positive potential. An SHR signal is pulsed to sample charge off storage region 70 through transistors 50 and 60 onto a capacitor in sample-and-hold circuit 265′. Next TX signal is pulsed high again. If anti-fuse element 20 is programmed, the floating diffusion region 70, previously set at a positive potential, will be flooded with electrons from the Vcmn supply ground signal. Thus, storage region 70 is pulled towards ground. If anti-fuse element 20 is not programmed, storage region 70 will remain floating at positive potential. Accordingly, a charge corresponding to the programmed or non-programmed state of memory cell 10 is stored in storage region 70. The final voltage of the storage region will be referred to as V_{AF}. SHS signal is pulsed to sample V_{AF} through transistors 50 and 60 onto a capacitor in sample-and-hold circuit 265′.

FIG. 5B shows a shortened timing diagram for a readout similar to FIG. 5A. In the FIG. 5B readout, the reset of region 25 is incorporated within the readout, allowing for a slightly accelerated readout.

FIG. 5C shows a timing diagram for a readout that does not correspond to a normal pixel readout, but provides improved signal-to-noise ratio in memory cell 10 readout in certain memory cell embodiments, as will be described further below. In this readout Vcmn is set to Vaapix and Vrst is set to ground. A correlated double sampling readout of a memory cell 10 is initiated by a RowSel pulsed high to select a pixel row for readout. Then RST signal is also pulsed high while the reset supply voltage is set to ground to reset floating diffusion region 70 to ground. SHS signal is pulsed to sample the charge on floating diffusion region 70 through transistors 50 and 60 onto a capacitor in sample-and-hold circuit 265′. After time Δt1, TX signal is pulsed high. The non-overlap time Δt1 between SHS and TX prevents a SHS signal pull-down path in storage region 70 from competing with a TX signal pull-up path. If anti-fuse element 20 is programmed, a current will flow by virtue of the voltage line Vcmn being set to Vaa-pix, a normal pixel operating voltage. Thus, storage, region 70 is pulled towards Vaa-pix. If anti-fuse element 20 is not programmed, storage region 70 will remain floating at ground. Accordingly, a charge V_{AF} corresponding to the programmed or non-programmed state of memory cell 10 is stored in storage region 70.

A time Δt2 after TX signal was pulsed high, RST signal drops low, allowing for an overlap equal to Δt2 of the TX signal high and RST signal high. Overlap Δt2 quickly attenuates the voltage rise on storage region 70 by providing a low impedance path to ground. The RST signal drop marks the beginning of an integration period, t_{INT}. Since the TX signal is still high, charge flows from storage region 70 to the line Vcmn which is at Vaa-pix. Next, SHR signal is pulsed during integration to sample charge off storage region 70 through transistors 50 and 60 to another capacitor in sample-and-hold circuit 265′. The SHR signal then drops, marking the end of integration period t_{INT}. TX signal remains high for a time Δt3 before dropping low. The TX signal overlap of time Δt3 prevents storage region 70 from leaking any charge, i.e., darkcurrent or photocurrent, which could drop the potential of the storage region 70 after the transfer transistor 30 is turned off.

The sampled reset voltage Vrst and the anti-fuse voltage V_{AF} are subtracted in differential amplifier 267′ which then has a signal representing whether anti-fuse element 20 was programmed or not. This signal is digitized by ADC 275′ and provided to an image processor 280′, which then has a signal representing a logic state of the anti-fuse element 20.

As shown in FIG. 3A, the memory cell 10 is easily integrated into a pixel array 200′ along with the imaging pixels, with only a slight modification to the fabrication of a conventional imaging array 200 by the substitute of an anti-fuse element 20 for a photosensor element 21 and by addition of voltage line Vcmn. The use of multiple column or banks of memory would allow a defined amount of re-programablity. Blocks of memory could be reserved for a second or third re-program, etc. each block would be one-time programmable, but the redundant blocks would allow re-writes. As an alternative and as shown in FIG. 3B and FIG. 3C, memory cell 10 may be part of a separate memory cell array 300, but may still employ the programming and readout timing as described with respect to FIG. 5A, 5B or 5C.

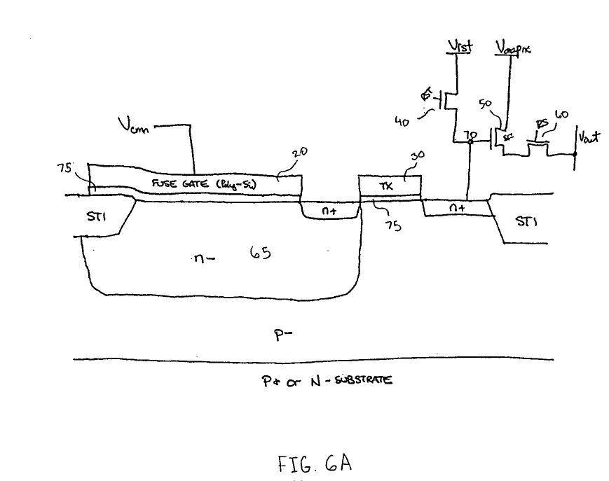

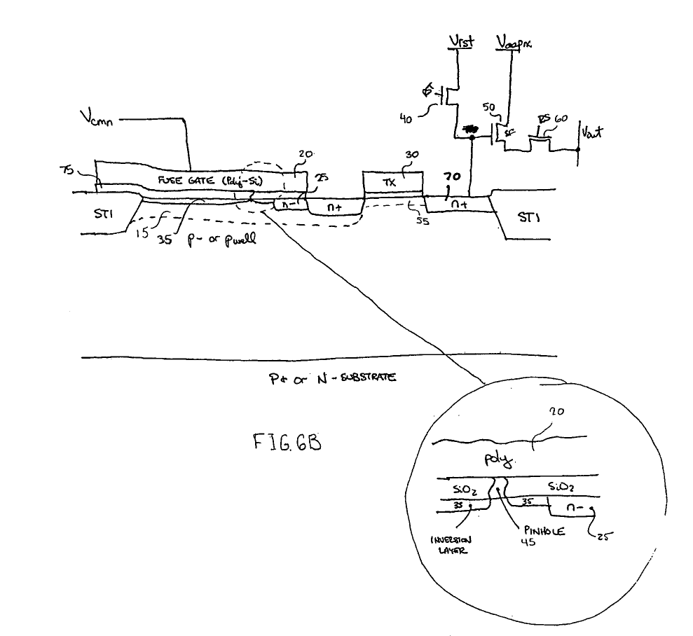

FIG. 6A shows a semiconductor level view of an embodiment of an anti-fuse element 20, implemented as a MOSFET cell with a transfer transistor 30. Anti-fuse element 20 is fabricated over an n-well 65 in a semiconductor substrate to allow application of a ground or positive potential Vcmn to the well during programming. Accordingly, this embodiment may be readout using any of the readout timing diagrams (FIG. 5A, FIG. 5B, FIG. 5C) described above.

FIG. 6B shows a semiconductor level view of an embodiment of an anti-fuse element 20 implemented as a MOSFET cell fabricated over a p-type region, such as a P-well or epi layer, in a semiconductor substrate. This embodiment is optimal for the readout described in FIG. 5C above, in which Vcmn should be set to ground. During a readout integration period, storage region 70 has a charge set by a current which passes through a pinhole 45 formed in the oxide 75, through a depletion region 15 and through a conductive channel 55 under a transfer transistor 30. A conductive layer 35 is formed under anti-fuse element 20 due to a positive gate bias of voltage Vaa-pix via Vcmn. Conductive layer 35 significantly reduces the series resistance between the pin-hole 45 and source/drain terminal of transfer transistor 30, making the anti-fuse readout more robust to any leakage charge to the p-epi or p-well that could contaminate the signal charge on the source/drain terminal of transfer transistor 30 and the floating diffusion region 70. The series resistance can be further reduced by increasing the diffusion overlap of anti-fuse element 20 by any number of measures know in the art, for example, including a Pch angled phosphorus halo implant 25 to place phosphorus further under the edge of the anti-fuse element 20. Accordingly, storage region 70 will reach a charge corresponding to the Vaa-pix voltage of the line Vcmn faster and more efficiently, sharpening the contrast between programmed cells and unprogrammed cells and increasing the accuracy of the readout.

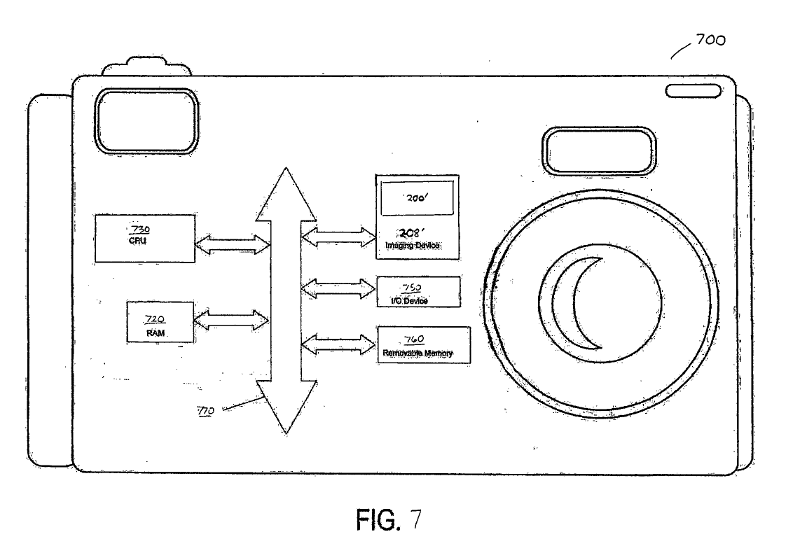

FIG. 7 is a block diagram of a processing system, for example, a camera system 700 having a lens 710 for focusing an image on the pixel array of an imaging device in accordance with any of the embodiments described and illustrated above, e.g., FIG. 3A, 3B, or 3C, with FIG. 7 showing the 3A embodiment. Although illustrated as a camera system the system 700 may also be a computer system, a process control system, or any other system employing a processor. The system 700 includes a central processing unit (CPU) 720, e.g., a microprocessor, that communicates with the imaging device 208′ and one or more I/O devices 750 over a bus 770. It must be noted that the bus 770 may be a series of buses and bridges commonly used in a processor system, but for convenience purposes only, the bus 770 has been illustrated as a single bus. The processor system 700 may also include random access memory (RAM) device 720 and some form of removable memory 760, such a flash memory card, or other removable memory as is well known in the art.

The above description and drawings illustrate various embodiments of the invention, which is primarily the use of an anti-fuse non-volatile memory cell within an imaging array utilizing existing array readout circuitry. It is not intended that the present invention be limited to the illustrated embodiments. However, these embodiments may be modified, changed or altered. Other methods of programming or reading out the anti-fuse element can be incorporated. The invention is only limited to the appended claims.

What is claimed as new and desired to be protected by Letters Patent of the United States is:

1. A imaging device, comprising:
an array, comprising imaging pixels, and memory cells provided in at least a portion of the array, where at least one memory cell in a row of the array shares at least one control signal line with the imaging pixels of the row.

2. The imaging device of claim 1 wherein at least one memory cell comprises:
a programmable anti-fuse element, having a first node connected to a first voltage source line;
a storage region in a substrate;
a transfer transistor, connected between a second node of the anti-fuse element and the storage region;
a reset transistor connected between the storage region and a second voltage source line; and,
a source follower transistor, having a gate connected to the storage region, for providing an output signal.

3. The imaging device of claim 2, further comprising a row select transistor, connected to the source follower transistor, for controlling application of an output signal from the source follower transistor to an output line.

4. The imaging device of claim 2, further comprising a control circuit configured to provide signals that control the reset transistor and transfer transistor.

5. The imaging device of claim 2, wherein the storage region has a doping which is sufficient to prevent hot carrier damage to the transfer transistor and the reset transistor during a programming of the anti-fuse element.

6. The imaging device of claim 2, wherein a diffusion region is formed between the anti-fuse element and the transfer transistor, and the doping of the diffusion region is sufficient to prevent hot carrier damage to at least the transfer transistor and the reset transistor during a programming of the anti-fuse-element.

7. The imaging device of claim 2 wherein the at least one column of memory cells is located on an edge of the pixel array.

8. The imaging device of claim 1, wherein the array comprises at least one column of memory cells.

9. The imaging device of claim 1, wherein the at least one shared control signal line comprises a reset line.

10. The imaging device of claim 1, wherein the at least one shared control signal line comprises a transfer line.

11. The imaging device of claim 1, wherein the at least one shared control signal line comprises a row select line.

12. The imaging device of claim 1, wherein the at least one shared control signal line comprises a reset control line, and a column select control line.

13. The imaging device of claim 12, wherein the at least one shared control signal line further comprises a transfer control line.

14. The imaging device of claim 1, wherein the anti-fuse element comprises a capacitor structure.

15. The imaging device of claim 1, wherein the anti-fuse element comprises a MOS transistor.

16. The imaging device of claim 15, wherein the MOS transistor has a gate element and further comprises an angled n-type halo implant within a substrate under the edge of the gate element.

17. The imaging device of claim 15, wherein the anti-fuse element is provided over a p-type region in a substrate.

18. The imaging device of claim 15, wherein the anti-fuse element is provided over an n-type region in a substrate.

19. The imaging device of claim 1 further comprising a control circuit for controlling readout of the memory cells.

20. The imaging device of claim 19, wherein the control circuit is configured to control the readout of imaging pixels and memory cells.

21. A pixel array, comprising:
imaging pixels arranged in rows and columns of the array with a plurality of rows of the array each having imaging pixels and at least one memory cell, each of the memory cells containing an anti-fuse element.

22. The pixel array of claim 21 further comprising a control circuit for generating control signals on lines shared by the imaging pixels and memory cells.

23. The pixel array of claim 22 wherein each of the memory cells comprises:
a programmable anti-fuse element;
a transistor for controlling a programming voltage which is applied to the anti-fuse element;
a storage region in a substrate for storing a charge related to the programmed state of the anti-fuse element;
a reset transistor for resetting the storage region;
a source-follower transistor having a gate for receiving charge from the storage region; and
a row select transistor for outputting a signal produced by the source-follower transistor.

24. The pixel array of claim 23, wherein the anti-fuse element comprises a capacitor structure.

25. The pixel array of claim 23, wherein the anti-fuse element comprises a MOS transistor.

26. The pixel array of claim 23, wherein each of the imaging pixel comprises:
a photosensor for accumulating charge;
a transfer transistor connected to the photosensor for controlling a transfer of charge from the photosensor;
a storage region connected to the photosensor for receiving charge from the photosensor via the transfer transistor;
a reset transistor connected to the storage region for resetting charge stored in the storage region to a given level;
a source-follower transistor connected to the storage region for amplifying a signal from the storage region; and
a row-select transistor connected to the source-follower transistor for receiving an amplified signal from the source-follower and controlling an output of the amplified signal.

27. An imaging device, comprising:
a pixel array containing imaging pixels arranged in rows and columns and at least one memory cell arranged in a row of the array and containing an anti-fuse element;
the imaging pixels of each row comprising a first storage region for storing first reset charges and second image generated charges and a readout circuit for reading out the first and second charges from the first storage region;
the at least one memory cell of the row comprising a second storage region for storing third reset charges and fourth charges representing the state of the anti-fuse element and a readout circuit for reading out the third and fourth charges from the second storage region.

28. An imaging device, comprising:
a pixel array containing imaging pixels arranged in rows and columns;
a memory cell array containing memory cells arranged in rows and columns, wherein at least one memory cell comprises:
a programmable anti-fuse element, having a first node connected to a first voltage source line;
a storage region in a substrate;
a transfer transistor, connected between a second node of the anti-fuse element and the storage region;
a reset transistor connected between the storage region and a second voltage source line; and,
a source follower transistor, having a gate connected to the storage region, for providing an output signal; and
a control circuit for controlling operation of the pixel array and the memory cell array.

29. The imaging device of claim 28, wherein the anti-fuse element comprises a capacitor structure.

30. The imaging device of claim 28, wherein the anti-fuse element comprises a MOS transistor.

31. The imaging device of claim 28, further comprising a row select transistor, connected to the source follower transistor, for controlling application of an output signal from the source follower transistor to an output line.

32. The imaging device of claim 29, further comprising readout circuitry for receiving a first output signal from the pixel array and a second output signal from the memory cell array.

33. A method of programming a memory cell, the method comprising:
selectively applying a first voltage from a reset voltage supply line of a pixel array to a substrate storage region in a memory cell substrate;
applying a second voltage to one side of the anti-fuse element; and
selectively connecting another side of the anti-fuse element to the storage region, the first and second voltages being sufficient to program the anti-fuse element.

34. The method of claim 33 wherein the first voltage is set to ground.

35. The method of claim 33 further comprising operating a first transistor to selectively apply the first voltage.

36. The method of claim 33, further comprising operating a second transistor to control a connection between the anti-fuse element and the storage region.

37. A method of programming a memory cell containing an anti-fuse element, the memory cell being provided in an array containing imaging pixels fabricated on a substrate, which receive a voltage from an array reset line, the method comprising:
operating a first reset transistor to apply a first voltage on the reset line to a storage region in the substrate;
applying a second voltage to one side of the anti-fuse element; and
operating a second transistor to connect another side of the anti-fuse element to the storage region, the first and second voltages being sufficient to program the anti-fuse: element.

38. A method of reading a memory cell containing an anti-fuse element, the memory cell being provided in an array containing imaging pixels fabricated on a substrate, the method comprising:
selectively applying a first voltage to a storage region in the substrate to reset the storage region;
sampling a first signal produced by charge at the reset storage region;
applying a second voltage to one side of the anti-fuse element;
connecting a second side of the anti-fuse element to the storage region to produce a charge in the storage region representing the state of the anti-fuse element; and
sampling a second signal produced by the charge from the storage region representing the state of the anti-fuse element.

39. The method of claim 38, further comprising disconnecting the second side of the anti-fuse element from the storage region.

40. The method of claim 38, further comprising transferring the first sampled signal and the second sampled signal to a circuit for providing a signal representing a state of the memory cell.

41. The method of claim 38, wherein the application of the second voltage to the storage region is controlled by operating a first transistor.

42. The method of claim 41, wherein the connecting of the anti-fuse to the storage region is controlled by operating a second transistor.

43. The method of claim 42, further comprising generating a first control signal for operating the first transistor and a second control signal for operating the second transistor, wherein the first control signal overlaps the second control signal.

44. The method of claim 42 further comprising generating a third control signal for sampling a signal representing the first charge and a fourth control signal for sampling a signal representing the second charge, wherein the third control signal does not overlap the second control signal.

45. The method of claim 44, wherein the fourth control signal terminates before termination of the second control signal.

46. A method of reading a memory cell containing an anti-fuse element, the memory cell being provided in an array containing imaging pixels fabricated on a substrate, the method comprising:
providing a ground path to one side of the anti-fuse element;
selectively applying a first voltage to set a first diffusion connected to a second side of the anti-fuse element to a positive voltage level;
selectively applying the first voltage to a storage region in the substrate to reset the storage region;
sampling a first signal produced by charge at the reset storage region;
connecting a second side of the anti-fuse element to the storage region to produce a charge in the storage region representing the state of the anti-fuse element; and
sampling a second signal produced by the charge from the storage region representing the state of the anti-fuse element.

47. A method of reading a memory cell containing an anti-fuse element, the memory cell being provided in an array containing imaging pixels fabricated on a substrate, the method comprising:
providing a ground path to one side of the anti-fuse element;
selectively applying a first voltage to set a first diffusion connected to a second side of the anti-fuse element to a positive voltage level;
selectively applying the first voltage to a storage region in the substrate to reset the storage region;
connecting a second side of the anti-fuse element to the storage region to produce a charge in the storage region representing the state of the anti-fuse element; and
sampling a signal produced by the charge from the storage region representing the state of the anti-fuse element.

48. The method of claim 47, wherein the first diffusion and the storage region are reset simultaneously.

49. A system comprising:
a processor;
an imaging device coupled to the processor, the imaging device comprising a pixel array comprising imaging pixels arranged in rows and columns, and memory cells in at least a portion of the array, where at least one memory cell in a row of the array shares at least one control signal line with the imaging pixels of the row.

50. The system of claim 49 wherein the system is, a still or video digital camera system.

51. The system of claim 50, wherein the at least one memory cell comprises:
a programmable anti-fuse element, having a first node connected to a first voltage source line;
a storage region in a substrate;
a transfer transistor, connected between a second node of the anti-fuse element and the storage region;
a reset transistor connected between the storage region and a second voltage source line;
a source follower transistor, having a gate connected to the storage region, for providing an output signal; and
a row select transistor, connected to the source follower transistor, for controlling application of an output signal from the source follower transistor to an output line.

52. The system of claim 51, wherein at least one column containing memory cells is located on an edge of the pixel array.

53. The system of claim 51, wherein the anti-fuse element comprises a capacitor structure.

54. The system of claim 51, the anti-fuse element comprises a MOSFET.

55. The system of claim 51, where the system is a camera system having a lens for focusing an image onto the pixel array.

56. The system of claim 51, further comprising a control circuit to program and readout the memory cells.

57. The system of claim 56, wherein the control circuit also controls application of signals to operate the imaging pixels of the array.

58. The system of claim 56, wherein at least one memory cell in a row of the array shares at least one control signal line with the imaging pixels of the row.

59. The system of claim 58, wherein the at least one shared control signal line comprises a reset line.

60. The system of claim 58, wherein the at least one shared control signal line comprises a transfer line.

61. The system of claim 58, wherein the at least one shared control signal line comprises a row select line.

62. A system comprising:
a processor;
an imaging device coupled to the processor, the imaging device comprising a pixel array comprising imaging pixels arranged in rows and columns; and
a memory cell array coupled to the processor comprising memory cells arranged in rows and columns, wherein at least one memory cell comprises:
a programmable anti-fuse element, having a first node connected to a first voltage source line;
a storage region in a substrate;
a transfer transistor, connected between a second node of the anti-fuse element and the storage region;
a reset transistor connected between the storage region and a second voltage source line;
a source follower transistor, having a gate connected to the storage region, and a source/drain connected to the second voltage line for providing an output signal; and
a row select transistor, connected to the source follower transistor, for controlling application of an output signal from the source follower transistor to an output line

63. The system of claim 62, further comprising a first control circuit for controlling the pixel array.

64. The system of claim 63, further comprising a second control circuit for controlling the memory array.

65. A memory array, comprised of memory cells arranged in rows and columns, where at least one memory cell comprises:
a programmable anti-fuse element, having a first node connected to a first voltage source line;
a storage region in a substrate;
a transfer transistor, connected between a second node of the anti-fuse element and the storage region;
a reset transistor connected between the storage region and a second voltage source line;
a source follower transistor, having a gate connected to the storage region, and a source/drain connected to the second voltage line for providing an output signal; and
a row select transistor, connected to the source follower transistor, for controlling application of an output signal from the source follower transistor to an output line

66. The memory array of claim 65, wherein the anti-fuse element comprises a capacitor structure.

67. The memory array of claim 65, wherein the anti-fuse element comprises a MOS transistor.
